(19) United States
(12) Patent Application Publication
(10) Pub. No.: US 2014/0055991 A1
(43) Pub. Date: Feb. 27, 2014

(54) Printed Circuit Boards with Deformations

(71) Applicants: Forrest Starnes McCanless, Oxford, GA (US); Patrick A. Collins, Conyers, GA (US)

(72) Inventors: Forrest Starnes McCanless, Oxford, GA (US); Patrick A. Collins, Conyers, GA (US)

(21) Appl. No.: 13/592,645

(22) Filed: Aug. 23, 2012

(51) Int. Cl. F21V 17/16; F21V 7/00; H05K 3/00; F21V 21/00

(52) U.S. Cl. 362/235; 362/249.02; 29/829

(57) ABSTRACT

A metal core printed circuit board that is mechanically deformed so as to improve the mechanical properties (e.g., improved section modulus or stiffness) of the board. The board is configured to be self-retaining such that it retains the deformation(s) without the help of other support structure. More specifically, the metal layer in the board is plastically (and permanently) deformed so as to retain the deformation(s) in the board.

### FIELD

Embodiments of the present invention relate to printed circuit boards having deformations.

### BACKGROUND

Printed circuit boards used for high-performance LED general lighting often use metal-core printed circuit boards (“MCPCB”). A MCPCB typically includes a metal (e.g., aluminum) base (as opposed to the traditional reinforced plastic base) onto which a dielectric layer is applied. A layer of copper is positioned on top of the dielectric layer. The LEDS are positioned on the copper layer, which acts as a circuit layer for electrical connections.

Metal core boards (i.e., onto which the traces are created during fabrication and onto which the components are placed during assembly) are generally available only in 1.0, 1.6, and 3.0 millimeter (mm) thicknesses. To optimally locate surface-mount LED packages for the desired optical characteristics, the boards may need to be relatively large and/or narrow. The manufacturing process by which such boards are populated often results in warping of the boards and thus in warped MCPCBs, which renders it difficult to mount the resulting MCPCBs in close contact to an underlying heat sink for the desired thermal performance. As a result, often the thicker, more expensive 1.6 or 3.0 mm metal core blanks, which are better able to resist warping, are used to make MCPCBs. In addition, many small fasteners are used to attach the board to the underlying heat sink to ensure the desired contact therebetween.

### SUMMARY

Certain embodiments of the present invention provide a metal core printed circuit board that is mechanically deformed so as to improve the mechanical properties (e.g., improved section modulus or stiffness) of the board. The board is configured to be self-retaining such that it retains the deformation(s) without the help of other support structure. More specifically, the metal layer in the board is plastically (and permanently) deformed so as to retain the deformation(s) in the board.

The terms “invention,” “the invention,” “this invention” and “the present invention” used in this patent are intended to refer broadly to all of the subject matter of this patent and the patent claims below. Statements containing these terms should not be understood to limit the subject matter described herein or to limit the meaning or scope of the patent claims below. Embodiments of the invention covered by this patent are defined by the claims below, not this summary. This summary is a high-level overview of various aspects of the invention and introduces some of the concepts that are further described in the Detailed Description section below. This summary is not intended to identify key or essential features of the claimed subject matter, nor is it intended to be used in isolation to determine the scope of the claimed subject matter. The subject matter should be understood by reference to the entire specification of this patent, all drawings and each claim.

### BRIEF DESCRIPTION OF THE FIGURES

Illustrative embodiments of the present invention are described in detail below with reference to the following drawing figures:

FIG. 1 is a top perspective view of an embodiment of a traditional metal core printed circuit board.

FIG. 2 is top perspective view of a metal core printed circuit board according to one embodiment.

FIG. 3 is a bottom perspective view of the metal core printed circuit board of FIG. 2.

FIG. 4 is a top perspective view of a portion of the metal core printed circuit board of FIG. 2, exposing the various layers of the board according to one embodiment.

FIG. 5. is a top partial perspective view of a metal core printed circuit board according to another embodiment.

FIG. 6 is a top partial perspective view of a metal core printed circuit board according to still another embodiment.

FIG. 7 is an enlarged section view taken at inset circle 7 of FIG. 6.

### DETAILED DESCRIPTION

The subject matter of embodiments of the present invention is described here with specificity to meet statutory requirements, but this description is not necessarily intended to limit the scope of the claims. The claimed subject matter may be embodied in other ways, may include different elements or steps, and may be used in conjunction with other existing or future technologies. This description should not be interpreted as implying any particular order or arrangement among or between various steps or elements except when the order of individual steps or arrangement of elements is explicitly described.

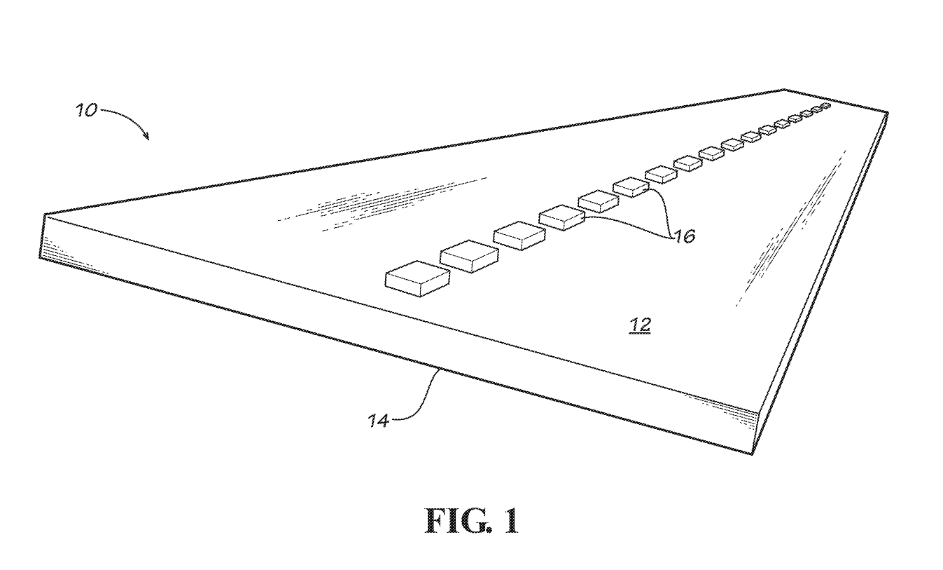

Certain embodiments of the present invention provide a metal core printed circuit board that is mechanically deformed so as to improve the mechanical properties (e.g., improved section modulus or stiffness) of the board. FIG. 1 illustrates an embodiment of a traditional MCPCB, which includes a metal core board 10 having an upper surface 12 and a lower surface 14. The upper surface 12 of the board is populated with a plurality of LEDs 16.

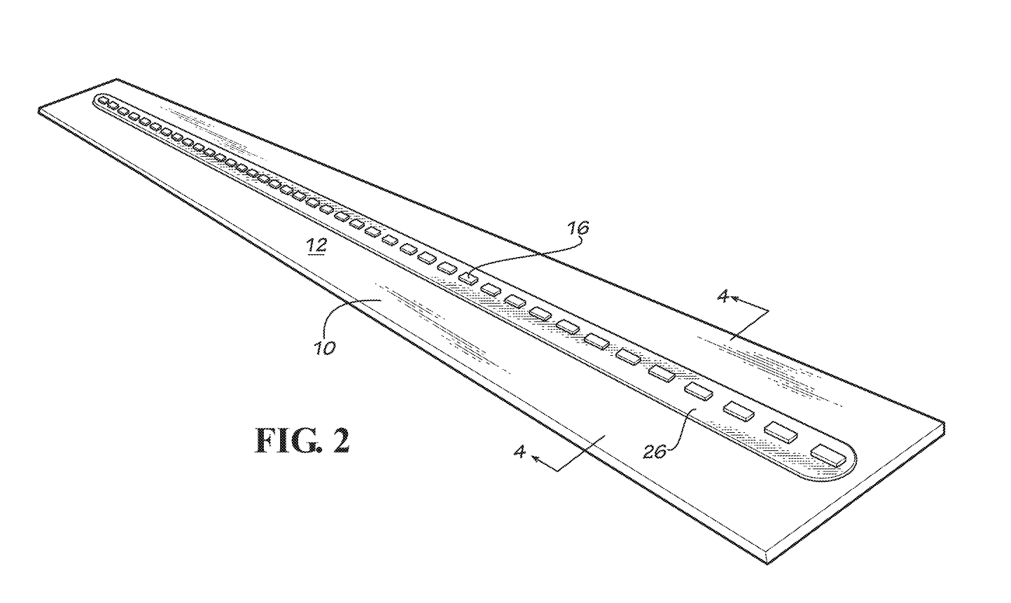

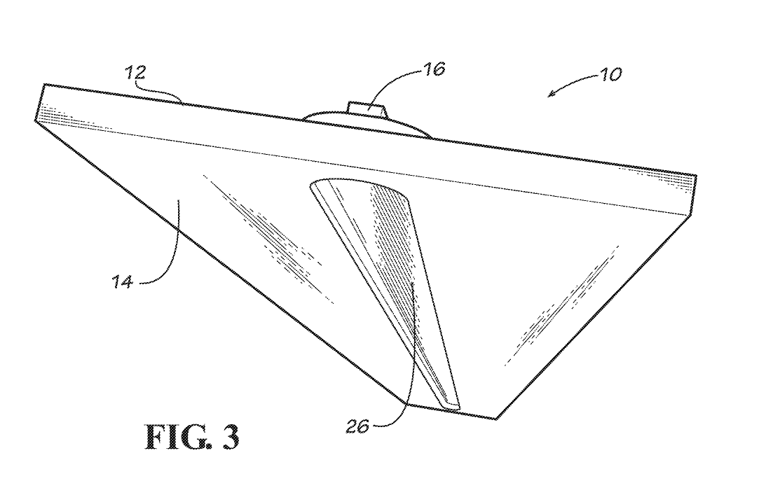

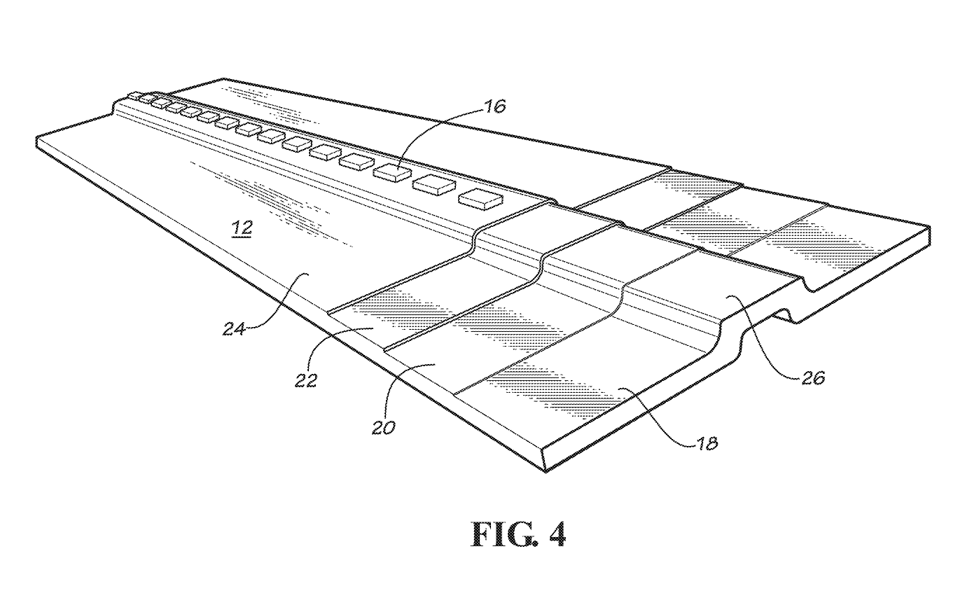

FIGS. 2-4 disclose an embodiment of the board 10 of FIG. 1, which includes a metal layer 18, a dielectric layer 20, a copper layer 22, and a plurality of LEDs 16. A reflective solder mask 24 may optionally be provided on top of the copper layer 22 to reflect the emitted light as desired. The board 10 has been mechanically deformed to form a deformation 26. More specifically, the deformation 26 is provided as a rib or boss that extends along the length of the board.

The rib 26 is provided on the board 10 so as to elevate the LEDs 16 above the plane of the board 10 so that they seat higher on the board 10 than they otherwise would. In addition to imparting stiffness to the board 10, the rib 26 elevates the LEDs 16 so that they can seat further into an associated lens (not shown) and will have a greater chance of being oriented above other components on the board 10 that can block low-angle light emitted from the LEDs 16. Thus, this configuration increases the chances of capturing the often-wasted low-angle light and thus contributes to lighting efficiencies.

The board 10 is configured to be self-retaining such that it retains the deformation 26 without the help of other support structure. More specifically, the metal layer 18 in the board 10 is plastically (and permanently) deformed so as to retain the deformation 26 in the board 10. In some embodiments, the metal layer 18 in the board 10 is at least 1.0 mm thick.

It may be desirable to use a metal core board having a resilient dielectric layer 20 in that the dielectric layer is both stretchable and flexible/bendable so that it can elastically deform so as to prevent the dielectric layer 20 from both cracking and delaminating during the deformation process. One example of such a resilient dielectric layer is sold by Dupont™ under the tradename CooLam™.

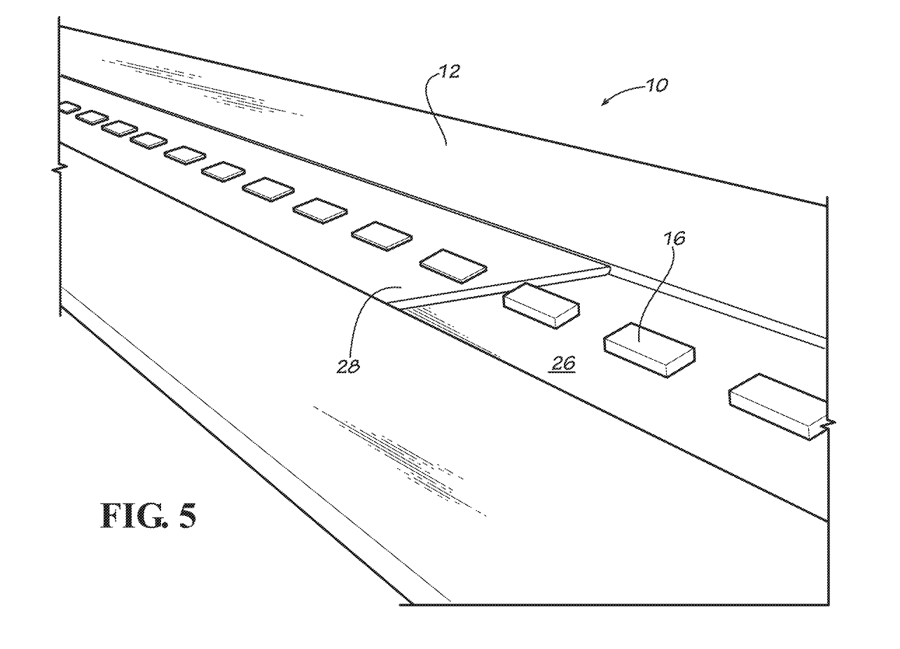

While the embodiment of FIGS. 2-4 illustrates a deformation 26 as a single rib extending along the length of the board 10 so as to elevate the LEDs 16, other types deformations 26 are contemplated herein. Any number of deformations 26 may be provided on the board 10 and they can be of any shape or size. By way only of example, a single, continuous deformation 26 need not be provided on the board 10. Rather, a plurality of isolated deformations 26 may also be provided on the board 10. While they certainly can, the deformations 26 need not alter the elevation or positioning of the LEDs 16 on the board 10. Furthermore, the deformations 26 can extend above the plane of the board (e.g., FIGS. 2-4) or below the plane of the board (e.g., FIGS. 5-7).

By way only of example, FIG. 5 illustrates a board 10 having a deformation 26 that extends below the plane of the board 10. In this embodiment, the LEDs 16 are seated within the deformation 26 such that the light-emitting surface of the installed LEDs 16 is essentially flush with the top surface 12 of the board 10. The area of the deformation 26 surrounding the LEDs 16 can be, but does not have to be, filled with a potting compound 28. The potting compound 28 can fill the entire area of the depression 26, but in some embodiments it may not. In FIG. 5 and for purposes of illustration, the potting compound 28 is shown filling only part of the depression 26. In some embodiments, the potting compound 28 may have a high reflective index (e.g., above 95%) to help reflect light emitted by the LEDs 16.

Recession of the LEDs 16 below the top surface 12 or plane of the board 10 can protect and mechanically strengthen the LEDs 16 from side impact. Provision of a potting compound 28 around the LEDs 16 protects the LEDs 16 against the weather and other conditions that can detrimentally impact their efficient operation. Moreover, such an embodiment imparts a polished looked to the board 10 by creating a board 10 with essentially a flat top surface 12 with isolated areas that emit light.

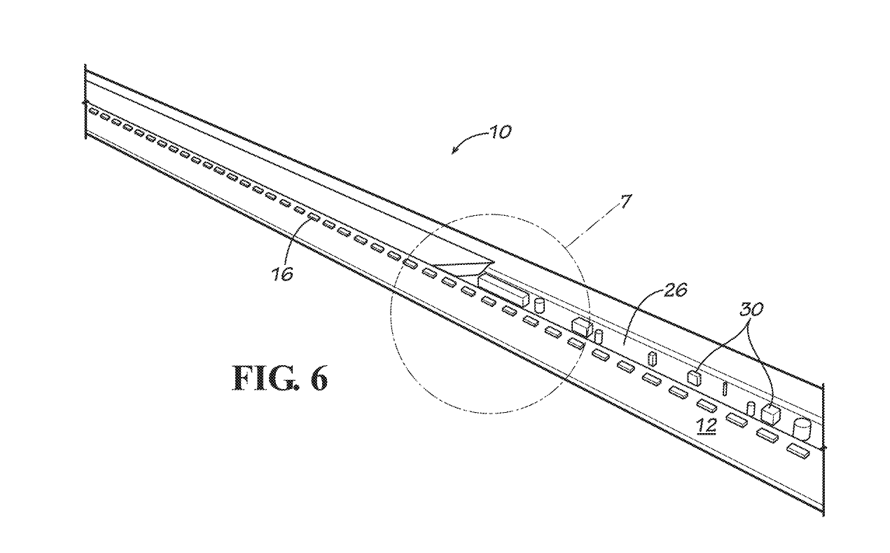

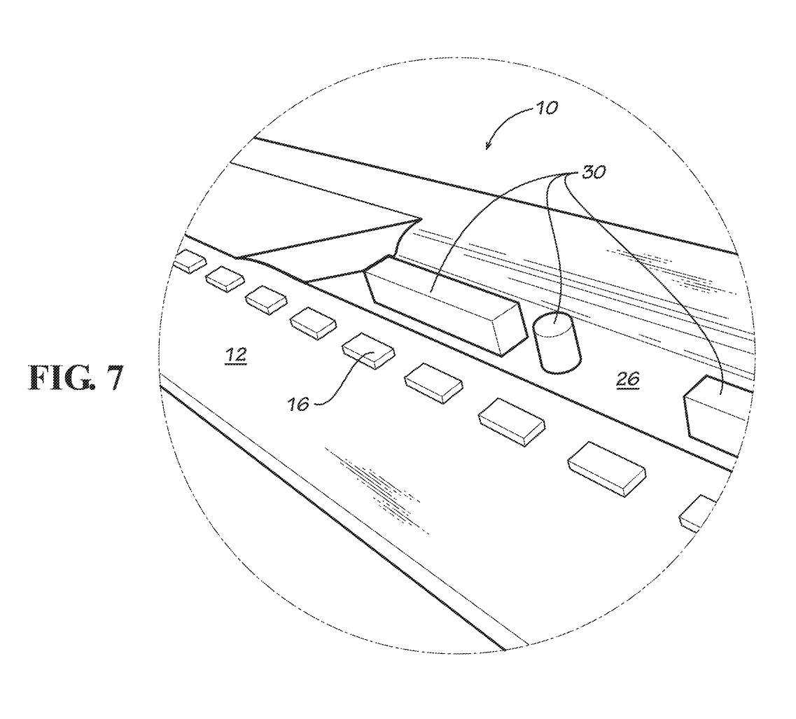

FIGS. 6 and 7 illustrate another embodiment where the deformation 26 extends downwardly in the board 10, below the plane of the board 10. In this embodiment, the LEDs 16 are not provided within the deformation 26, however. Rather, other electronic, non-LED components (generally donated by 30) are positioned within the deformation 26. Provision of the components 30 within the deformation 26 prevents them from blocking (or at least eliminates the likelihood that they will block) low-angle light from the LEDs 16.

The deformation 26 may be filled with a potting compound 28 to entirely or partially encapsulate the components 30 resident in the deformation and thereby protect them. In some embodiments, the potting compound 30 is highly-reflective to help reflect light emitted by the LEDs.

The deformation(s) 26 may be provided on the board 10 prior to or after the board 10 is populated with LEDs 16. Various techniques may be used to impart the deformation(s) 26 to a board 10, including, but not limited to, embossing, bead rolling, hydroforming, punching, coining, etc.

Imparting stiffness to the board 10 using deformations 26 improves the manufacturing quality of the boards 10 by reducing the likelihood that such boards 10 will warp or distort during manufacture. Thus, thinner, less expensive metal core boards (1.0 mm vs. 1.6 or 3.0 mm) can be used. Moreover, because the boards 10 are better able to retain their planar nature, they are more apt to lie flat upon, and thus help ensure the desired contact with, a heat sink. Consequently, fewer fasteners are required to attach the boards to an associated heat sink to ensure such contact.

The foregoing is provided for purposes of illustrating, explaining, and describing embodiments of the present invention. Further modifications and adaptations to these embodiments will be apparent to those skilled in the art and may be made without departing from the scope or spirit of the invention. Different arrangements of the components depicted in the drawings or described above, as well as components and steps not shown or described are possible. Similarly, some features and subcombinations are useful and may be employed without reference to other features and subcombinations. Embodiments of the invention have been described for illustrative and not restrictive purposes, and alternative embodiments will become apparent to readers of this patent. Accordingly, the present invention is not limited to the embodiments described above or depicted in the drawings, and various embodiments and modifications can be made without departing from the scope of the claims below.

We claim:

1. A printed circuit board comprising:
a) a board extending in a plane and comprising at least one metal layer and at least one deformation formed with the board and extending above or below the plane, wherein the board is capable of self-retaining the at least one deformation; and
b) a plurality of LEDs mounted on the board.

2. The printed circuit board of claim 1, wherein the at least one deformation comprises a rib that extends above the plane of the board.

3. The printed circuit board of claim 1, wherein the at least one deformation extends above the plane of the board and wherein at least one of the plurality of LEDs is mounted on the at least one deformation so that the at least one deformation elevates the at least one LED above the plane of the board.

4. The printed circuit board of claim 1, wherein the at least one deformation extends below the plane of the board and wherein at least one of the plurality of LEDs is mounted in the at least one deformation so that the at least one deformation lowers the at least one LED below the plane of the board.

5. The printed circuit board of claim 1, further comprising at least one non-LED electrical component mounted on the board, wherein the at least one deformation extends below the plane of the board and wherein the at least one non-LED electrical component is mounted in the at least one deformation so that the at least one deformation lowers the non-LED electrical component below the plane of the board.

6. The printed circuit board of claim 1, further comprising a potting compound positioned within the at least one deformation.

7. The printed circuit board of claim 6, wherein the potting compound comprises a reflective material.

8. The printed circuit board of claim 1, wherein the board further comprises a resilient dielectric layer located above the metal layer.

9. The printed circuit board of claim 1, wherein the at least one deformation is formed by embossing, bead rolling, hydroforming, punching, or coining.

10. The printed circuit board of claim 1, wherein the metal layer comprises a thickness of at least 1 millimeter.

11. The printed circuit board of claim 1, wherein the metal layer deforms to retain the at least one deformation in the board.

12. A method of forming a metal core printed circuit board comprising
(a) providing a board comprising at least one metal layer, wherein the board extends in a plane;
(b) forming at least one deformation with the board, wherein the at least one deformation extends above or below the plane and wherein the board is capable of self-retaining the at least one deformation; and
(c) mounting a plurality of light emitting diodes on the board.

13. The method of claim 12, wherein mounting the plurality of light emitting diodes on the board occurs before the at least one deformation is formed in the board.

14. The method of claim 12, wherein mounting the plurality of light emitting diodes on the board occurs after the at least one deformation is formed in the board.

15. The method of claim 12, wherein the at least one deformation extends above the plane of the board and wherein mounting a plurality of light emitting diodes on the board comprises mounting at least one of the plurality of LEDs on the at least one deformation so that the at least one deformation elevates the at least one LED above the plane of the board.

16. The method of claim 12, wherein the at least one deformation extends below the plane of the board and wherein mounting a plurality of light emitting diodes on the board comprises mounting at least one of the plurality of LEDs in the at least one deformation so that the at least one deformation lowers the at least one LED below the plane of the board.

17. The method of claim 12, wherein the at least one deformation extends below the plane of the board and wherein the method further comprises mounting at least one non-LED electrical component in the at least one deformation so that the at least one deformation lowers the electrical component below the plane of the board.

18. The method of claim 12, further comprising providing a reflective potting compound in the at least one deformation.

19. The method of claim 12, wherein forming the at least one deformation in the board comprises embossing, bead rolling, hydroforming, punching, or coining the at least one deformation in the board.

20. The method of claim 12, wherein forming the at least one deformation in the board comprises deforming the at least one metal layer in the board to retain the at least one deformation in the board.

21. A printed circuit board comprising:
(a) a board extending in a plane and comprising:
a metal layer;
a dielectric layer located above the metal layer, wherein the dielectric layer is resilient; and
at least one deformation formed with the board and extending above the plane of the board, wherein the board is capable of self-retaining the at least one deformation; and
(b) a plurality of LEDs mounted on the at least one deformation.
